(19) United States
(12) Patent Application Publication
(10) Pub. No.: US 2019/0296264 A1
(43) Pub. Date: Sep. 26, 2019

(54) QUANTUM DOT BASED PIXEL ASSEMBLY

(71) Applicant: Apple Inc., Cupertino, CA (US)

(72) Inventors: Mathew Mathai, San Jose, CA (US); Jonathan S. Steckel, Cupertino, CA (US); Hitoshi Yamamoto, Palo Alto, CA (US)

(21) Appl. No.: 16/216,656

(22) Filed: Dec. 11, 2018

Related U.S. Application Data
(60) Provisional application No. 62/647,969, filed on Mar. 26, 2018.

(51) Int. Cl. H01L 51/52; H01L 27/32; H01L 51/50

(52) U.S. Cl. CPC H01L 51/5265; H01L 27/3244; H01L 51/502; H01L 51/5206; H01L 51/5221; H01L 2251/558; H01L 51/5072; H01L 51/5088; H01L 51/5092; H01L 2251/5353; H01L 51/5056

(57) ABSTRACT

Display panel narrow band emission pixels and methods of fabrication are described. In an embodiment, such a pixel arrangement includes a pair of reflective electrodes, a pair of narrow band emission layers, and a pair of hole transport layers of different thickness over the pair of reflective electrodes and narrow band emission layers. A semi-transparent or transparent top electrode layer is located over the first and second hole transport layers.

### RELATED APPLICATIONS

This application claims the benefit of priority of U.S. Provisional Application No. 62/647,969 filed Mar. 26, 2018 which is incorporated herein by reference.

### BACKGROUND

### Field

Embodiments described herein relate to quantum dots. More particularly, embodiments relate to quantum dots in quantum dot LED displays.

### Background Information

State of the art displays for phones, tablets, computers and televisions utilize glass substrates with thin-film transistors (TFTs) to control transmission of backlight through pixels based on liquid crystals. More recently emissive displays such as those based on organic light emitting diodes (OLED) have been introduced because they can have a faster response time, and be more power efficient, allowing each pixel to be turned off completely when displaying black or dark colors. Even more recently, quantum dot light emitting diodes (QD-LEDs) have been introduced as an alternative display technology, potentially being more power efficient than OLEDs.

Quantum dots are semiconductor materials where the size of the structure is small enough (e.g. less than tens of nanometers) that the electrical and optical characteristics differ from the bulk properties due to quantum confinement effects. For example, the emission properties of quantum dots are related to their size and shape in addition to their composition. When an electric field is applied to a QD-LED electrons and holes move into the quantum dot layer where the electrons and holes are captured in the quantum dots and recombine, emitting photos. The emission wavelength can be tuned by changing the size of the quantum dots. Typically, smaller quantum dots emit bluer light (higher energy) and larger quantum dots emit redder light (lower energy).

### SUMMARY

Display panel narrow band emission pixels and methods of fabrication are described. In an embodiment, a display panel narrow band emission pixel includes at least a first subpixel and a second subpixel. Each subpixel includes a corresponding reflective electrode (e.g. cathode), narrow band emission layer, and hole transport layer of different thickness over the corresponding reflective electrode and narrow band emission layer. Specifically, embodiments describe inverted pixel structures in which hole transport layers (HTL) with variable thicknesses, and hence tunable cavities, are located nearer a top transparent or semi-transparent anode layer, than to a more reflective cathode layer. The inclusion of a narrow band emitter facilitates inherent color gamut, which is less dependent on the micro cavity thickness compared to OLED. Location of the micro cavities closer the transparent anode layer may increase luminance. Additionally, a distance between the narrow band emission layers and reflective cathode layers can be minimized, reducing color shift vs. viewing angle.

### BRIEF DESCRIPTION OF THE DRAWINGS

FIG. 1 is a schematic side view illustration of an inverted pixel stack-up in accordance with an embodiment.

FIG. 2 is schematic side view illustration of an OLED stack-up.

FIG. 3 is a schematic side view illustration of a pixel stack-up in accordance with an embodiment.

FIG. 4 is a schematic side view illustration of a pixel stack-up in accordance with an embodiment.

### DETAILED DESCRIPTION

Embodiments describe narrow band emission pixels and display panels including the same. In particular, embodiments describe an inverted narrow band emission pixel stack. In an embodiment, a display panel narrow band emission pixel includes at least a first subpixel and a second subpixel, and a semi-transparent or transparent top electrode layer over corresponding first and second hole transport layers (HTLs). For example, the first subpixel may include a first reflective electrode, a first emission layer over the first reflective electrode, where the first emission layer is designed for a first narrow band emission wavelength range, and a first (HTL characterized by a first thickness over the first emission layer. The second subpixel may include a second reflective electrode, a second emission layer over the second reflective electrode, where the second emission layer designed for a second narrow band emission wavelength range that is different from the first narrow band emission wavelength range, and a second HTL characterized by a second thickness over the second emission layer, wherein the second thickness is different from the first thickness.

In one aspect, embodiments leverage the integration of narrow band emitters with tunable micro cavities to achieve systems with high current efficiency, while mitigating color shift over viewing angle. Specifically, embodiments describe inverted pixel structures, in which hole transport layers (HTL) with variable thicknesses, and hence tunable cavities, are located nearer a top transparent or semi-transparent anode layer, than to a more reflective cathode layer. Foremost, this allows for precise micro cavity tuning with the HTL to a narrow wavelength range. In addition, such a configuration may allow for pixel structures in which a thickness variation between the narrow band emission layers and the cathodes is much smaller than the wavelength of emitted light (e.g. one order magnitude less). This may lead to less deviation in color shift, and overall dependence of viewing angle on thickness variation.

In accordance with embodiments, narrow band emission may be defined by emission peaks of the emission layers of 35 nm or less full-width-at-half-maximum (FWHM). Narrow band emission layers may be achieved using emitters such as quantum dots specifically, though other materials may be used where appropriate. Narrow band emission is distinguishable from conventional OLED emission layers, which are commonly understood-as having a broadband internal spectrum. It has been observed that while broadband internal spectrum achieved with OLED may achieve good gamut, this is coupled with reduced efficiency at the narrowed output spectrum. Thus, embodiments may potentially achieve significantly higher current efficiencies compared to OLED displays.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over”, or “on” another layer or bonded “to” or in “contact” with another layer may be directly in contact with the other layer or may have one or more intervening layers. One layer “between” layers may be directly in contact with the layers or may have one or more intervening layers.

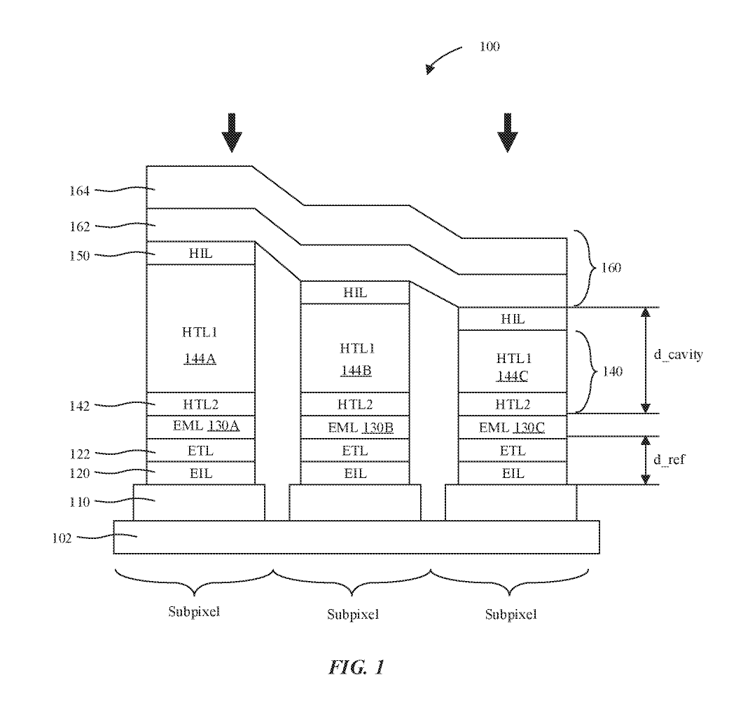

Referring now to FIG. 1 a schematic side view illustration is provided of an inverted pixel stack-up in accordance with an embodiment. The particular pixel arrangement illustrated in FIG. 1 is that of a three color system, such as red-green-blue, though this is merely an exemplary application, and embodiments are not limited to such arrangements. As shown, the pixel stack-up is formed over a substrate 102, that may be designed for top emission (e.g. viewing direction from top side as shown by the arrows). The display substrate may be any suitable rigid or flexible substrate, and may include working circuitry, such as thin film transistors (TFT) or metal oxide semiconductor (MOS) transistors. In an embodiment, working circuitry is contained within pixel driver chips that are integrated with the substrate 102. Each subpixel may have a corresponding cathode 110. The cathodes 110 may be formed of a variety of electrically conductive materials, including reflective, transparent, or semi-transparent materials. In an embodiment, the cathodes 110 are characterized as being more reflective to the corresponding emission wavelength for the subpixel than the anode 160. Exemplary cathode materials include Al, Ca/Mg, Sm/Au, Yb/Ag, Ca/Ag, Ba/Ag, and Sr/Ag. For example, in a double layer Ca/Mg the Ca layer has a low work-function for electron injection, whereas a Mg capping layer improves electrical conductance of the cathode. The cathodes 110 may be formed by thermal evaporation or sputtering followed by patterning using photolithography, for example, through a fine metal mask including an opening for each subpixel.

As shown, each subpixel may contain an electron injection layer (EIL) 120, electron transport layer (ETL) 122, an emission layer (EML) designed for a narrow band emission wavelength range, a hole transport layer (HTL) 140, hole injection layer (HIL), and anode 160. EIL 122 may be a common layer shared by multiple subpixels within a pixel, and may be a common layer across multiple pixels. Alternatively, the EIL 122 may be formed separately for each subpixel. The EIL 122 facilitates the injection of negative charge (electrons) from the cathode 110 into the ETL 122. EIL 120 may be formed of alkali metal salts such as LiF, low work function metals such as Ca, Ba, and n-doped material (e.g. combination of electron transport material and electron donating material). In an embodiment, the EIL 120 is formed by thermal evaporation.

ETL 122 is optionally formed on the EIL 120. In accordance with embodiments, the ETL 122 may be a common layer shared by multiple subpixels within a pixel, and may be a common layer across multiple pixels. Alternatively, the ETL 122 may be formed separately for each subpixel. The ETL 122 may be a high electron mobility layer that transports negative charge (electrons) into the EML 130 (e.g. 130A, 130B, 130C) and physically separates the EIL 122 from the EML 130. ETL 122 may be formed of electron deficient organic small molecules (e.g. substituted benzimidazoles), inorganic metal oxides or semiconductor nanoparticles, inorganic metal oxide or semiconductor sol-gel materials, organometallic compounds, and organic polymers. The ETL 122 may be formed using techniques such as spin coating, ink jet printing, slot die coating, nozzle printing, contact printing, gravure printing, any solution printing technology, as well as thermal evaporation.

As shown, EMLs 130A, 130B, 130C are formed on the optional ETL(s) 122. In accordance with embodiments, the EMLs 130A, 130B, 130C may be formed or patterned only in separate subpixels. Each EML 130 may include materials designed for narrow band emission, such as light emitting nanoparticles (e.g. quantum dots) that emit light at the desired wavelength and full width at half max. Exemplary nanoparticles include spherical, rod shaped, platelet (2D quantum well) including semiconductor materials such as CdSe, InP, GaSe, etc. The EMLs 130A, 130B, 130C may be formed using techniques such as spin coating, ink jet printing, slot die coating, nozzle printing, contact printing, gravure printing, and any solution printing technology. In an embodiment EMLs 130 may be formed by transfer printing an array of quantum dot layers into an array of subpixels.

As shown, a HTL 140 is optionally formed on the EMLs 130. In accordance with embodiments, the HTL 140 may include multiple layers. Additionally, thickness of HTL 140 may be tuned for each subpixel to create a specified micro cavity. Thus, HTL may have two roles, to adjust cavity strength and to ensure the layer next to the EML 130 has a higher band gap than that of the emissive species itself. The HTL 140 transports positive charge (holes) to the EMLs 130, and physically separates the HIL 150 from the EML 130. HTL 140 may be formed of electron rich organic small molecules such as arylamines, polyfluorene derivatives or organic polymer materials. HTL 140 may also be formed with other materials such as inorganic metal oxides or semiconductor nanoparticles or inorganic metal oxide or semiconductor sol-gel materials. The HTL 140 may be formed using techniques such as spin coating, ink jet printing, slot die coating, nozzle printing, contact printing, gravure printing, any solution printing technology, as well as thermal evaporation.

In the embodiment illustrated, HTL 140 includes multiple layers, including priming HTL 142, and cavity inducing HTL 144 (e.g. 144A, 144B, 144C). In the embodiment illustrated, priming HTL 142 is a common layer. Priming HTL 142 may provide the requisite band gap difference from the EMLs 130, and also provide a uniform baseline thickness for cavity creation. The cavity inducing HTL 144 may then be precisely formed to requisite thickness in the individual subpixels. In this manner, thickness variation can be more closely controlled.

An HIL 150 is formed over the HTLs 140. In accordance with embodiments, the HIL 150 may be a common layer shared by multiple subpixels within a pixel, and may be a common layer across multiple pixels. Alternatively, the HIL 150 may be formed separately for each subpixel. The HIL 150 facilitates the injection of positive charge (holes) from the anode 160 into the HTL 140. The HIL 150 may be formed of materials such as conductive polymer-based materials (e.g. poly thiophenes, poly anilines), combination of arylamine based hole transport host and electron accepting dopant (e.g. charge transfer salts), strongly electron accepting small organic molecules, metal oxides. The HIL 150 may be formed using techniques such as spin coating, ink jet printing, slot die coating, nozzle printing, contact printing, gravure printing, any solution printing technology, as well as thermal evaporation.

Anode 160 may then be formed over the HIL. Anode 160 may be formed of a variety of electrically conductive materials. In an embodiment, anode 160 is formed of indium-tin-oxide (ITO). For example, ITO may be formed by sputtering or thermal evaporation. In an embodiment, anode 160 is a composite anode including a plurality of layers. For example, a composite anode 160 may include a metal layer 162 and/or transparent or semi-transparent conductive layer 164, such as ITO. This addition of a thin metal layer 162 may be utilized to adjust strength of the cavity. Additionally, thickness of the metal layer can be tuned to adjust cavity strength. Alternatively a thicker metal layer 162 may be used to form the anode, followed by the formation of an organic capping layer. For example, if the capping layer is refractive index matched to the an overlying thin film encapsulation, the composite of the organic capping layer, thin film encapsulation, and the rest of the stack-up in the display could behave more like a semi-infinite medium like glass in a bottom emission stack-up. Anode 160 may be a common layer shared by multiple subpixels within a pixel, and may be a common layer across multiple pixels. Alternatively, an array of anodes 710 can be sputtered onto the display substrate.

In accordance with embodiments, an implication of the inverted pixel structure with narrow band internal spectrum is that gamut may be inherently achievable, due to most photons being extracted within the micro cavity. Further, strength of the micro cavity may function largely to adjust luminance versus viewing angle. Still referring to FIG. 1, the micro cavity is largely tuned by adjusting the thickness (d_cavity) of the HTL 140 between the EML 130 and the light transmitting anode 160, while the thickness (d_ref) of the ETL/EIL 122/120 in contact with the thicker reflective cathode 110 remains thin. Thus, implication of this way of tuning the micro cavity is that the ETL/EIL thickenss variation is much smaller than the wavelength of light emitted from EML 130. As a result, overall dependence of viewing angle on thickness variation is reduced for the system. In an embodiment, d_ref is an order of magnitude smaller than the emission wavelengths. For example, d_ref may have a maximum thickness of 50 nm. Thus, the maximum thickness of d_ref on the order of tens of nanometers is much less than the wavelengths of the visible spectrum on the order of hundreds of nm. By way of comparison, exemplary thicknesses of d_cavity may be greater than 100 nm, such as 100 nm-300 nm, with larger thicknesses corresponding to pixels with higher wavelength emission spectra (e.g. red), and smaller thicknesses corresponding to pixels with smaller wavelength emission spectra (e.g. blue).

The inverted pixel structures with narrow band internal spectrum in accordance with embodiments may be distinguished from traditional OLED structures in several structural features and performance aspects. For example, traditional OLED structures use broadband emitters, and micro cavities to boost forward viewing luminance. One implication of this is that the broadband spectrum is narrowed by the micro cavity, which reduces overall efficiency that is achievable. Thus, the cavity strength affects the output spectrum and luminance simultaneously. This can also result in a large color shift as a function of viewing angle. It has additionally been observed that deviations in color shift and efficiency may be also be attributed to location of tuned cavity layers (e.g. HTL/HIL) nearer the more reflective electrode (e.g. commonly the anode) since the thickness variations in HTL/HIL near the more reflective electrode are on the same order of magnitude as the emission wavelength. In contrast, the inverted pixel structures with narrow band internal spectrum locate the tuned cavity layers (e.g. HTL/HIL) nearer the electrode that is more transmissive to the emission wavelength. In order to further illustrate such implications, simulations have been performed for Examples 1-4 of various pixel arrangements. Results of the simulation data are provided in Table 1.

TABLE 1

| | Example 1 | Example 2 | Example 3 | Example 4 |
|---|---|---|---|---|
| Characterization | OLED top | QD-substituted | QD- | Inverted |
| | emission | OLED | substituted | QD top |
| | structure | top emission | OLED | emission |
| | | structure | bottom | structure |
| | | | emission | |
| | | | structure | |
| Viewing | Top side | Top side | Bottom side | Top side |
| direction | | | | |
| White (RGB) | 86 | 154 | 61 | 162 |
| current efficiency | | | | |
| (cd/A) | | | | |
| Color shift (dE) | 17 | 5 | 5 | 12 |
| at 60 degrees | | | | |
| viewing angle | | | | |

### Example 1

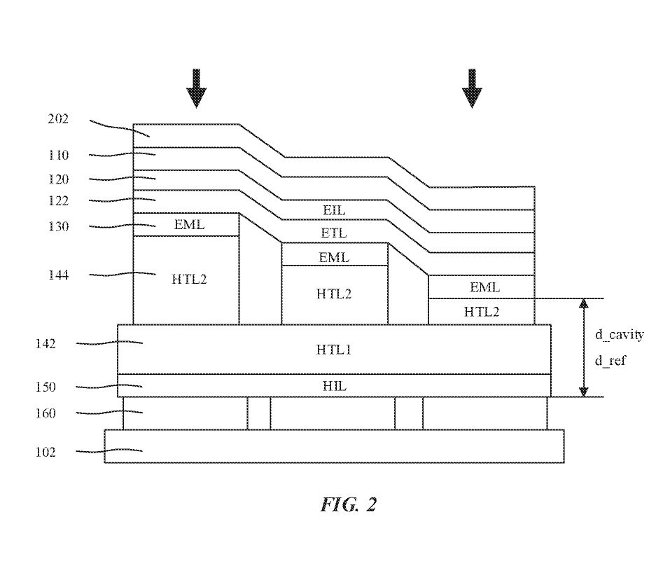

FIG. 2 is schematic side view illustration of an OLED top emission stack-up structure used as basis for simulation data of Example 1. Top emission OLED electroluminescent spectrum emission vs. viewing angle was simulated using n,k data (refractive index, extinction coefficient) for organic layers and using thicknesses for each layer typically used in display relevant device stacks. The emissive layer 130 spectra used for the simulation are measured photoluminescence spectra of the individual red, green and blue organic emitters. These are typically on the order of 25-40 nm full width at half maximum (FWHM) for blue, and 40-60 nm FWHM for Green and red. For the simulation some degree of dipole orientation was assumed (proportion of horizontally resolved to vertical resolved dipole orientation was kept at 90%). In order to achieve maximum out-coupling of light, the distance of the emissive layer 130 to the anode 160 has to be adjusted for each color. This is done by including an additional thickness of hole transporting layer (cavity inducing HTL 144) between the anode 160 layer and the emissive layers 130 in case of green and red. For example the red, green and blue HTL thickness can be 180, 148 and 120 nm respectively. The current state of the art in displays achieves this either by printing into individual red, green or blue sub-pixel wells or by the use of fine metal masks for selective vapor deposition into the sub pixel areas. Furthermore the emissive layer 130 to cathode 110 distance is also optimized in order to ensure minimum exciton quenching by the metal cathode while at the same time achieving the desired on axis color. In this example a thickness of 16 nm was used. The thickness of the cathode 110 can also impact the overall cavity strength (attenuation of the FWHM of the emissive layer spectrum vs. the inherent emissive layer spectrum) and is typically varied between 8 to 25 nm. An organic capping layer 202 is additionally considered to be formed over the stack, and may be refractive index matched to thin film encapsulation of the display. The simulations were carried out with a commercial software package.

### Example 2

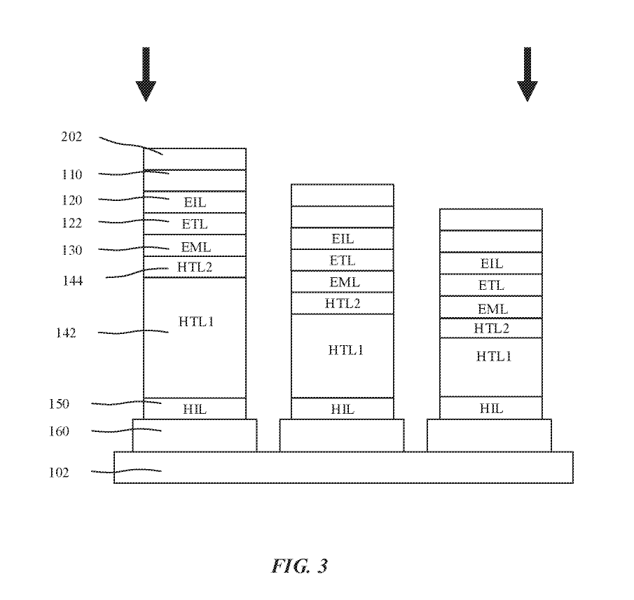

FIG. 3 is a schematic side view illustration of a QD-substituted OLED top emission structure pixel stack-up in accordance with an embodiment used as basis for simulation data of Example 2. In the case of Example 2, the emissive layers 130 for red, green and blue are considered to be quantum dot based materials. Accordingly the FWHM used in the simulations were 20 nm for blue, and 35 nm for red and green. The FWHM values were picked based on known state of the art for quantum dot emission, though these values are exemplary, and embodiments are not limited to these specific values. The emissive layer 130 thickness is typically 45 nm. Here too dipole orientation of 90% was used in the assumptions. This can be achieved in case of quantum dots with specific aspect ratios that can ensure the emissive dipole has a fixed orientation relative to the film itself.

### Example 3

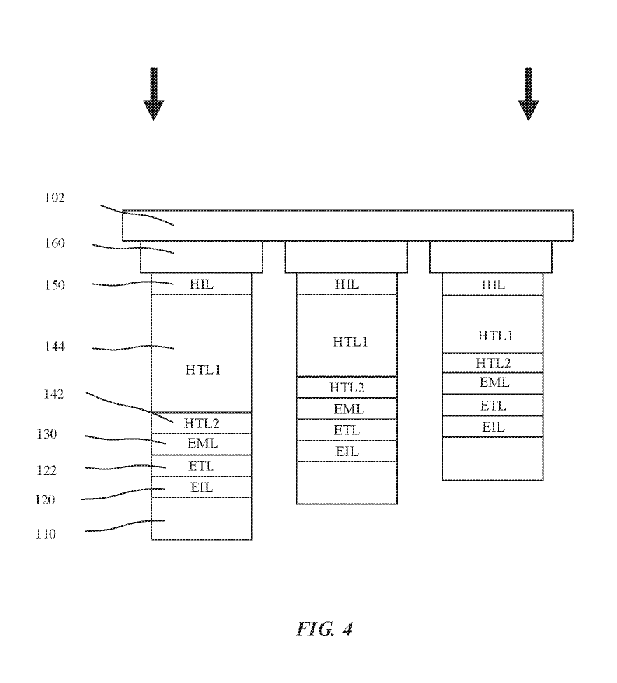

FIG. 4 is a schematic side view illustration of a QD-substituted OLED bottom emission structure pixel stack-up in accordance with an embodiment used as basis for simulation data of Example 3. For Example 3 the emission is considered to be taking place through a thicker (for example 70 nm) transparent electrode (anode 160) such as indium tin oxide with the respective red, green blue diodes having their individual hole transport layer (142, 144) thickness adjusted to achieve the optimum distance between the emissive layer and the transparent electrode. The opposite electrode (cathode 110) is typically a thick (100 nm) metal layer such as aluminum. In this case very low color shift vs. viewing angle is observed. However this also results in less light output in the forward direction. In the case of mobile displays, it is desirable to have the light emission cone maximized with reference to the viewer and this achieved by adjusting the cavity strength.

### Example 4

FIG. 1 is a schematic side view illustration of a pixel stack-up in accordance with an embodiment used as basis for simulation data of Example 4. In the case of Example 4, the device is constructed using a top emission architecture. However, unlike the other top emission architectures of Examples 1-2, the reflective electrode (cathode 110) is used to inject electrons. An example of such an electrode would be silver. Due to its work function mismatch to inject electrons, an additional injection layer or surface treatment is envisioned that incorporates a low work function metal salt coated on top of the electrode. The thickness of this layer is 1-5 nm. Furthermore a thin ETL 122 such as zinc oxide is envisioned to be coated over the respective red, green and blue sub pixel areas on top of the reflective electrode. In the simulated example a common thickness of 16 nm is used. The same emission layers described in Example 2 are considered in this example. Unlike more conventional top emission architectures, the cavity dimension for each color is adjusted between the emission layer 130 and the top electrode (anode 160) through which light emission takes place. This ensures that the thickness variation inherent to any coating process is not influencing the emitter location relative to the reflective electrode (cathode 110). This in turn reduces the variation in luminance vs. viewing angle expected for individual colors. Given that quantum dots have narrow emission to begin with, the color shift vs. viewing angle is already within acceptable limits. A hole injection layer 150 may be inserted between the hole transport layer 144 and the transparent anode 160 layer. The anode 160 layer itself can be a composite anode including a thin (10 nm) metal layer 162 such as silver and an additional thicker conductive layer 164 such as indium tin oxide (ITO, 70 nm). The composite electrode can be used to tune the strength of the micro-cavity thus ensuring that the luminance vs. angle can be optimized.

Referring again to FIG. 1, in an embodiment, a display panel narrow band emission pixel 100 include a first subpixel including a first reflective electrode (e.g. cathode 110), a first emission layer 130A over the first reflective electrode (cathode 110), with the first emission layer designed for a first narrow band emission wavelength range, and a first HTL (142, 144A) characterized by a first thickness over the first emission layer 130A. The display panel narrow band emission pixel 100 additionally includes a second subpixel including a second reflective electrode (e.g. cathode 110), a second emission layer 130C over the second reflective electrode (cathode 110), with the second emission layer designed for a second narrow band emission wavelength range that is different from the first narrow band emission wavelength range, and a second HTL (142, 144C) characterized by a second thickness over the second emission layer 130C, where the second thickness is different from the first thickness. A semi-transparent or transparent top electrode layer 160 is located over the first and second hole transport layers.

In accordance with embodiments, the first narrow band emission wavelength range, and the second narrow band emission wavelength range are both 35 nm or less full-width-at-half-maximum. The first emission layer 130A may include quantum dots of a first composition (e.g. red emitting quantum dots), and the second emission layer 130C may include quantum dots of a second composition (e.g. blue emitting quantum dots).

In accordance with embodiments, the first reflective electrode 110 is more reflective to the first narrow band emission wavelength range than the top electrode layer 160. In addition, a first distance (d_ref) from a top surface of the first reflective electrode 110 to a bottom surface of the first emission layer 130A is approximately the same as a second distance (d_ref) from a top surface of the second reflective electrode 110 to a bottom surface of the second emission layer (EML 130C). For example, the first distance and the second distance are less than 50 nm.

A common electron transport layer (ETL) 122 may be located underneath the first emission layer 130A and the second emission layer 130B, and over the first reflective electrode 110 and the second reflective electrode 110. Additionally, a common electron injection layer (EIL) 120 may be located underneath the common ETL 122, and over the first reflective electrode 110 and the second reflective electrode 110.

In an alternative configuration, a first ETL 120 is located underneath the first emission layer 130A and over the first reflective electrode 110, and a second ETL 120 is located underneath the second emission layer 130C and over the second reflective electrode 110.

A first distance (d_ref) from a top surface of the first reflective electrode 110 to a bottom surface of the first emission layer 130A, and a second distance (d_ref) from a top surface of the second reflective electrode 110 to a bottom surface of the second emission layer 130C are both less than 50 nm.

In an embodiment a common hole injection layer (HIL) 150 is located over the first HTL (142, 144A) and the second HTL (142, 144C).

The top electrode layer 160 may include a transparent conductive oxide (TCO) layer 164, or a layer stack, such as a stack including a metal layer 162 and TCO layer 164.

In accordance with embodiments, a first distance (d_ref from a top surface of the first reflective electrode 110 to a bottom surface of the first emission layer 130A is at least an order of magnitude less than a primary peak of the first narrow band emission wavelength range. For example, the primary peak of the first narrow band emission wavelength range may be between 620 nm and 750 nm. In an embodiment, the first distance is less than 50 nm. In an embodiment, a second distance from a top surface of the second reflective electrode 110 to a bottom surface of the second emission layer 130C is at least an order of magnitude less than a primary peak of the second narrow band emission wavelength range.

The display panel narrow band emission pixels in accordance with embodiments may include any number of subpixels. For example, a third subpixel may be included with a third reflective electrode 110, a third emission layer 130B over the third reflective electrode, the third emission layer designed 130B for a third narrow band emission wavelength range that is different from the first narrow band emission wavelength range and the second narrow band emission wavelength range, and a third HTL 144B characterized by a third thickness over the third emission layer, wherein the third thickness is different from the first thickness of the first HTL 144A and the second thickness of the second HTL 144C. As shown in FIG. 1, the semi-transparent or transparent top electrode layer 160 is over the first, second, and third hole transport layers.

In accordance with embodiments, third narrow band emission wavelength range is 35 nm or less full-width-at-half-maximum, a the third emission layer 13B includes quantum dots of a third composition (e.g. for green emission), the second reflective electrode 110 is more reflective to the second narrow band emission wavelength range than the top electrode layer 160, and the third reflective electrode 110 is more reflective to the third narrow band emission wavelength range than the top electrode layer 160.

In utilizing the various aspects of the embodiments, it would become apparent to one skilled in the art that combinations or variations of the above embodiments are possible for forming a narrow band emission pixel and display including the same. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A display panel narrow band emission pixel comprising:
a first subpixel comprising:
a first reflective electrode;
a first emission layer over the first reflective electrode, the first emission layer designed for a first narrow band emission wavelength range; and
a first hole transport layer (HTL) characterized by a first thickness over the first emission layer; and
a second subpixel comprising:
a second reflective electrode;
a second emission layer over the second reflective electrode, the second emission layer designed for a second narrow band emission wavelength range that is different from the first narrow band emission wavelength range; and
a second HTL characterized by a second thickness over the second emission layer, wherein the second thickness is different from the first thickness; and
a semi-transparent or transparent top electrode layer over the first and second hole transport layers.

2. The display panel of claim 1, wherein the first narrow band emission wavelength range, and the second narrow band emission wavelength range are both 35 nm or less full-width-at-half-maximum.

3. The display panel of claim 2, wherein the first emission layer comprises quantum dots of a first composition, and the second emission layer comprises quantum dots of a second composition.

4. The display panel of claim 2, wherein the first reflective electrode is more reflective to the first narrow band emission wavelength range than the top electrode layer.

5. The display panel of claim 4, wherein a first distance from a top surface of the first reflective electrode to a bottom surface of the first emission layer is approximately the same as a second distance from a top surface of the second reflective electrode to a bottom surface of the second emission layer.

6. The display panel of claim 5, wherein the first distance and the second distance are less than 50 nm.

7. The display panel of claim 5, further comprising a common electron transport layer (ETL) underneath the first emission layer and the second emission layer, and over the first reflective electrode and the second reflective electrode.

8. The display panel of claim 7, further comprising a common electron injection layer (EIL) underneath the common ETL, and over the first reflective electrode and the second reflective electrode.

9. The display panel of claim 4, further comprising a first ETL underneath the first emission layer and over the first reflective electrode, and a second ETL underneath the second emission layer and over the second reflective electrode.

10. The display panel of claim 9, wherein a first distance from a top surface of the first reflective electrode to a bottom surface of the first emission layer, and a second distance from a top surface of the second reflective electrode to a bottom surface of the second emission layer are both less than 50 nm.

11. The display panel of claim 4, wherein a first distance from a top surface of the first reflective electrode to a bottom surface of the first emission layer, and a second distance from a top surface of the second reflective electrode to a bottom surface of the second emission layer are both less than 50 nm.

12. The display panel of claim 4, further comprising a common hole injection layer (HIL) over the first HTL and the second HTL.

13. The display panel of claim 4, wherein the top electrode layer comprises a transparent conductive oxide (TCO) layer.

14. The display panel of claim 4, wherein the top electrode layer comprises a layer stack.

15. The display panel of claim 14, wherein the layer stack includes a metal layer and a TCO layer.

16. The display panel of claim 4, wherein a first distance from a top surface of the first reflective electrode to a bottom surface of the first emission layer is at least an order of magnitude less than a primary peak of the first narrow band emission wavelength range.

17. The display panel of claim 16, wherein the primary peak of the first narrow band emission wavelength range is between 620 nm and 750 nm.

18. The display panel of claim 17, wherein the first distance is less than 50 nm.

19. The display panel of claim 16, wherein a second distance from a top surface of the second reflective electrode to a bottom surface of the second emission layer is at least an order of magnitude less than a primary peak of the second narrow band emission wavelength range.

20. The display panel of claim 4, further comprising a third subpixel comprising:
a third reflective electrode;
a third emission layer over the third reflective electrode, the third emission layer designed for a third narrow band emission wavelength range that is different from the first narrow band emission wavelength range and the second narrow band emission wavelength range; and
a third HTL characterized by a third thickness over the third emission layer, wherein the third thickness is different from the first thickness and the second thickness;
wherein the semi-transparent or transparent top electrode layer is over the first, second, and third hole transport layers; and
wherein the third narrow band emission wavelength range is 35 nm or less full-width-at-half-maximum, the third emission layer comprises quantum dots of a third composition, the second reflective electrode is more reflective to the second narrow band emission wavelength range than the top electrode layer, and the third reflective electrode is more reflective to the third narrow band emission wavelength range than the top electrode layer.
